(19) United States
(12) Patent Application Publication
(10) Pub. No.: US 2007/0171615 A1
(43) Pub. Date: Jul. 26, 2007

(54) HEAT DISSIPATION DEVICE

(76) Inventors: Wan-Lin Xia, Shenzhen (CN); Tao Li, Shenzhen (CN); Wei-Qiang Tian, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/307,110

(22) Filed: Jan. 24, 2006

(51) Int. Cl. H05K 7/20

(52) U.S. Cl. 361/700

(57) ABSTRACT

A heat dissipation device includes a heat sink (10) and a heat capacitor (20). The heat sink includes a base (12) attachable with a heat-generating electronic component (30) and a fin assembly (14) extending from the base. The fin assembly includes two supports (140) and each support has a plurality of first fins (142) parallel to the base and a plurality of second fins (144) perpendicular to the base. The heat capacitor includes a sealed container (22) made of a material with a heat conductivity and a heat-storing material (24) made of a phase-change thermal interface material to absorb heat generated by the heat-generating electronic component. The heat-storing material changes from solid state to liquid state upon absorbing the heat from the heat-generating electronic component.

### FIELD OF THE INVENTION

The present invention generally relates to a heat dissipation device for removing heat from an electronic component and particularly to a heat dissipation device which has a heat capacitor for storing heat received from the electronic component.

### DESCRIPTION OF RELATED ART

With advancement of computer technology, electronic devices operate with high speeds. It is well known that more rapidly the electronic devices operate, more heat they generate. If the heat is not dissipated duly, the stability of the operation of the electronic devices will be impacted severely.

Generally, in order to ensure the electronic device to run normally, a heat dissipation device is used to dissipate the heat generated by the electronic device.

However, when a suddenly high power surges through the heat-generating electronic component, it generates a suddenly large amount of heat. The suddenly increased large amount of heat, though appearing only for an instant, cannot be timely dissipated via the heat dissipation device. Accordingly, a suddenly high temperature of the heat-generating electronic component is caused. The suddenly high temperature of the heat-generating electronic component is possible to exceed its normal working temperature. When this happens, the heat-generating electronic component could be damaged and its lifespan could be affected. It is significant to enable the heat-generating electronic component to be held at a constant working temperature range, such that the heat-generating electronic component can avoid the damage or even malfunction due to the abrupt temperature raise because of the suddenly high power surge. Consequently, there is a need to provide a heat dissipation device that can quickly absorb the suddenly increased heat of the heating-generating electronic component to maintain the temperature of the heat-generating electronic component temperature within a predetermined range.

### SUMMARY OF INVENTION

A heat dissipation device in accordance with a preferred embodiment of the present invention comprises a heat sink and a heat capacitor attached on the heat-absorbing portion. The heat sink comprises a base attachable with a heat-generating electronic component and a fin assembly extending from the base. The fin assembly comprises two supports and each support comprises a plurality of fins extending in different directions. The heat capacitor comprises a sealed container made of a material with a high heat conductivity and a heat-storing material made of a phase-change thermal interface material and received in the container. The heat-storing material changes from solid state to liquid state upon receiving heat from the heat-generating electronic component, and from the liquid state to the solid state after releasing the heat.

Other advantages and novel features will become more apparent from the following detailed description of preferred embodiments when taken in conjunction with the accompanying drawings, in which:

### BRIEF DESCRIPTION OF DRAWINGS

FIG. 1 is an isometric view of a heat dissipation device in accordance with a preferred embodiment of the present invention;

FIG. 2 is an exploded view of FIG. 1; and

FIG. 3 is a bottom view of the heat dissipation device of FIG. 1 with a heat-generating electronic component.

### DETAILED DESCRIPTION

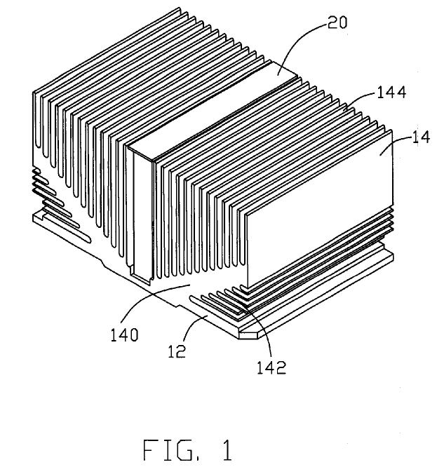

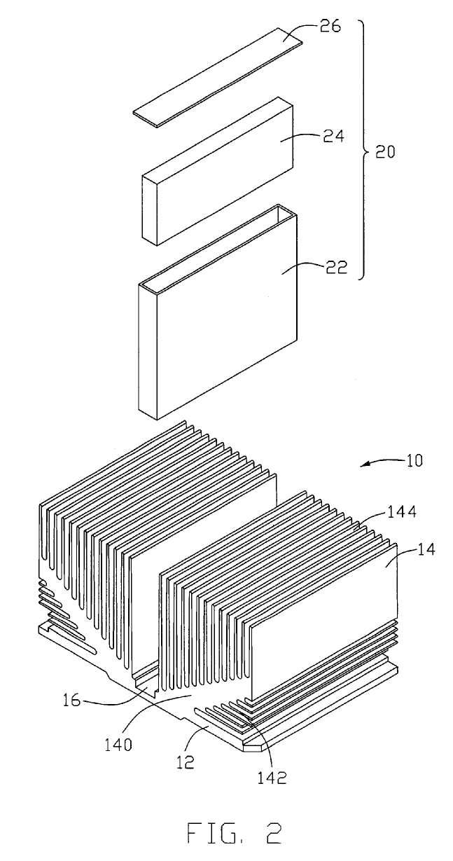

FIGS. 1-2 show a heat dissipation device in accordance with a preferred embodiment of the present invention. The heat dissipation device comprises a heat sink 10 and a heat capacitor 20 disposed in the heat sink. The heat sink 10 comprises a heat-absorbing portion, such as a base 12, and a heat-dissipating portion, such as a fin assembly 14 extending from the base 12. The heat capacitor 20 is arranged on the base 12 and in the fin assembly 14. The base 12 has a substantially plate-like configuration.

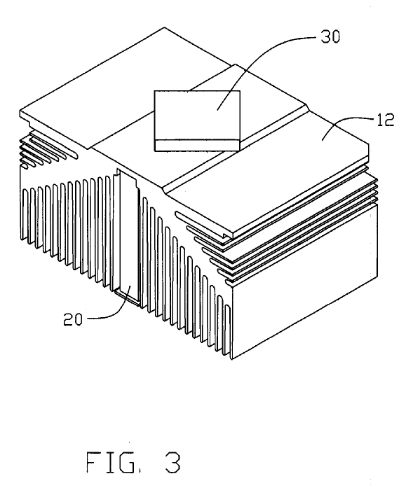

Referring to FIGS. 2-3, the base 12 has a bottom surface (not labeled) for contacting a heat-generating electronic component 30 and a top surface (not labeled) opposing the bottom surface. A groove 16 is defined in a center of the top surface of the base 12. The groove 16 divides the fin assembly 14 into two symmetrical parts. Each part of the fin assembly 14 comprises a support 140 extending upwardly and outwardly from a portion of the base 12 adjoining to the groove 16, a plurality of first fins 142 horizontally arranged on a bottom side of the support 140 and a plurality of second fins 144 upwardly arranged on a top side of the support 140. The first fins 142 are parallel to the base 12 and between the base 12 and the support 140, while the second fins 144 are perpendicular to the base 12.

The heat capacitor 20 is attached to the base 12 and received in the groove 16 by soldering means or by other conventional means such that a bottom surface of the heat capacitor 20 is thermally contacted with the top surface of the base 12 at a bottom extremity of the groove 16. The heat capacitor 20 is located just above the heat-generating electronic component 30. The heat capacitor 20 comprises a cubical container 22, a heat-storing material 24 accommodated in the container 22 and a cover 26 sealing a top opening of the container 22. The container 22 is preferably made of a metal with a high heat conductivity, such as aluminum or copper. The heat-storing material 24 is made of a phase-change material having a lower melting point, capable of changing from solid state to liquid state by absorbing heat from the heat-generating electronic component 30 and returning back to the solid state by releasing the heat stored therein. In the preferred embodiment, the heat-storing material 24 is a phase-change thermal interface material (TIM) sold by Bergquist company with a part name of Hi-Flow 225U or by Honeywell company with a part name of PCM45 Series Phase Change Thermal Interface Material.

When a high power suddenly surges through it, the heat-generating electronic component 30 produces excessive heat than normally expected; the heat capacitor 20 can quickly absorb the excessive heat which can not be duly dissipated out by the heat sink 10 and store the heat therein to maintain the temperature of the heat-generating electronic component 30 within an acceptable level. When the heat-generating electronic component 30 is returned to a normal operation or an idle and the heat generated by the heat-generating electronic component 30 is decreased, the heat sink 10 is available to absorb the excessive heat from the heat capacitor 20 and release the excessive heat to an ambient environment. Thus, the temperature of the heat-generating electronic component 30 can be maintained in a stable range.

In operation, when the heat generated by the heat-generating electronic component 30 exceeds a specified level, it is first transferred to the bottom of the base 12. A part of the heat on the base 12 is directly transferred to the supports 140 and then to the first and second fins 142, 144. The heat in the fin assembly 14 is dissipated along different directions perpendicular and parallel to the base 12. Another part of the heat is transferred to the heat capacitor 20 and absorbed by and stored in the heat-storing material 24 of the heat capacitor 20. Since the heat-storing material changes phase upon absorbing the heat, a large portion of the heat generated by the heat-generating electronic component 30 is conveyed to the heat capacitor 20. Accordingly the heat-generating electronic component 30 is cooled quickly and its temperature is stably maintained within a predetermined range.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A heat dissipation device comprising:
a heat-absorbing portion adapted for being attached to a heat-generating electronic component;
a heat-dissipating portion comprising a plurality of fins extending from the heat-absorbing portion and being disposed on the heat-absorbing portion; and
a heat capacitor attached to the heat-absorbing portion, the heat capacitor comprising a sealed container made of a material with a high heat conductivity and a heat-storing material made of a phase-change thermal interface material, the heat-storing material being received in the container, the heat-storing material changing from solid state to liquid state when absorbing heat from the heat-generating electronic component.

2. The heat dissipation device as claimed in claim 1, wherein the heat capacitor is located on the heat-absorbing portion and in the heat-dissipating portion.

3. The heat dissipation device as claimed in claim 2, wherein the heat-absorbing portion defines a groove receiving a bottom of the heat capacitor.

4. The heat dissipation device as claimed in claim 2, wherein the heat-absorbing portion is a plate-like base and the heat-dissipating portion is a fin assembly disposed on the base.

5. The heat dissipation device as claimed in claim 4, wherein the base defines a groove in a center thereof to divide the fin assembly into two parts.

6. The heat dissipation device as claimed in claim 5, wherein each part comprises a support extending from the base, a plurality of first and second fins arranged on two lateral sides of the support, the first and second fins being parallel and perpendicular to the base, respectively.

7. The heat dissipation device as claimed in claim 6, wherein a bottom of the heat capacitor is received in the groove.

8. A heat dissipation device comprising:
a base having a bottom surface for contacting a heat-generating electronic component thereon;
a fin assembly disposed on a top surface of the base, the fin assembly comprising two supports extending upwardly and outwardly from the base, each support comprising a plurality of fins arranged on two opposite sides thereof; and
a heat capacitor disposed on the top surface of the base and located corresponding to the heat-generating electronic component, the heat capacitor comprising a sealed container made of a material having a high heat conductivity and a heat-storing material disposed within the container;
wherein the heat-storing material is capable of changing from a first state to a second state by absorbing heat and changing from the second state to the first state by releasing the heat stored therein, and wherein the first state is a solid state and the second state is a liquid state.

9. The heat dissipation device as claimed in claim 8, wherein the heat-storing material is made of a phase-change thermal interface material.

10. The heat dissipation device as claimed in claim 9, wherein the heat capacitor is located on the base and in the fin assembly.

11. The heat dissipation device as claimed in claim 9, wherein the base defines a groove in the top surface thereof and a bottom of the heat capacitor is thermally contacted with the top surface of the base at a bottom extremity of the groove.

12. The heat dissipation device as claimed in claim 11, wherein each support comprises a plurality of first fins parallel to the base and a plurality of second fins perpendicular to the base.

13. The heat dissipation device as claimed in claim 12, wherein the fin assembly is divided into two symmetrical parts by the groove.

14. A heat dissipation device comprising:
a base having a bottom face contacting with a heat-generating electronic component;
a heat capacitor mounted to the base and located above the heat-generating electronic component; and
a plurality of fins extending from the base and located beside the heat capacitor, wherein the heat capacitor receives a phase-change thermal interface material therein, the phase-change thermal interface material changing from solid state to liquid state upon receiving heat from the heat-generating electronic component.

15. The heat dissipation device as claimed in claim 8, wherein each of the supports extends slantwise from the base, and there is an acute angle between the base and each of the supports.

16. The heat dissipation device as claimed in claim 15, wherein a plurality of first fins extends vertically from each of the supports, and a plurality of second fins extends horizontally from each of the supports, and the first and second fins are located at flanks of each of the supports.

17. The heat dissipation device as claimed in claim 16, wherein the first fins have different lengths along a vertical direction and the second fins have different lengths along a horizontal direction.

18. The heat dissipation device as claimed in claim 15, wherein the two supports form a V-shaped configuration extending from the base.
